(19) United States
(12) Patent Application Publication
(10) Pub. No.: US 2018/0020566 A1
(43) Pub. Date: Jan. 18, 2018

(54) ELECTRONIC DEVICE, CONTACTOR, AND ELECTRONIC DEVICE SYSTEM

(71) Applicant: FUJITSU LIMITED, Kawasaki-shi (JP)

(72) Inventors: Haruki Hirata, Fukuoka (JP); Kazuhiro Watanabe, Fukuoka (JP); Jun Oota, Fukuoka (JP)

(73) Assignee: FUJITSU LIMITED, Kawasaki-shi (JP)

(21) Appl. No.: 15/627,926

(22) Filed: Jun. 20, 2017

(30) Foreign Application Priority Data
Jul. 15, 2016 (JP) 2016-140922

(51) Int. Cl. H05K 7/14; G06F 1/18; H02G 5/00; B22C 1/16

(52) U.S. Cl. CPC H05K 7/1414; H05K 7/1435; B22C 1/165; G06F 1/189; H02G 5/005

(57) ABSTRACT

There is provided an electronic device including a terminal configured to receive power and be provided on a back surface side of the electronic device, the terminal including a hole portion configured to be concaved from the back surface side to a front surface side of the electronic device and include a first connection portion configured to be provided on the back surface side of the electronic device and include an inner circumferential surface having a female screw groove shape, and a second connection portion configured to be provided on an inner side of the first connection portion, and include an inner diameter smaller than an inner diameter of the first connection portion and an inner circumferential surface smoother than the inner circumferential surface of the first connection portion.

### CROSS-REFERENCE TO RELATED APPLICATION

This application is based upon and claims the benefit of priority of the prior Japanese Patent Application No. 2016-140922, filed on Jul. 15, 2016, the entire contents of which are incorporated herein by reference.

### FIELD

The embodiments discussed herein are related to an electronic device provided with a terminal to which power is supplied, an electronic device system, and a contactor.

### BACKGROUND

In the related art, there is an electronic device that is mounted on a rack having a power supply connector for power supply and is provided with a terminal to which power is supplied via the power supply connector. Such an electronic device is used by being mounted on the rack, or may be used by directly supplying power from the power supply cord without using the rack.

As a technique related to such multiple forms of use, for example, there is a technique relating to an electronic device with a terminal structure in which a printed circuit board is used by both a pin terminal block for pin connection provided with a pin connector and a screw terminal block for screw connection provided with a screw terminal fitting in the related art (for example, refer to Japanese Laid-open Patent Publication No. 10-134865). In the technique of Japanese Laid-open Patent Publication No. 10-134865, any one of the pin terminal block and the screw terminal block is selected and is attached to a case when using the electronic device.

### SUMMARY

According to an aspect of the invention, an electronic device includes a terminal configured to receive power and be provided on a back surface side of the electronic device, the terminal including a hole portion configured to be concaved from the back surface side to a front surface side of the electronic device and include a first connection portion configured to be provided on the back surface side of the electronic device and include an inner circumferential surface having a female screw groove shape, and a second connection portion configured to be provided on an inner side of the first connection portion, and include an inner diameter smaller than an inner diameter of the first connection portion and an inner circumferential surface smoother than the inner circumferential surface of the first connection portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view illustrating an entire configuration of a rack in a state where an electronic device according to First Embodiment is attached;

FIG. 2 is an exploded perspective view of the electronic device, the rack on which the electronic device is attached, a sub-rack, and a power supply bus bar according to First Embodiment;

FIG. 3 is an external perspective view of a connector-and-terminal block according to First Embodiment;

FIG. 4 is a partially sectional view of the connector-and-terminal block according to First Embodiment;

FIG. 5 is an external perspective view of power supply connectors according to First Embodiment;

FIG. 6 is a partially sectional view of the power supply connector according to First Embodiment;

FIG. 7 is a sectional view illustrating a state before a terminal and a contact pin according to First Embodiment are coupled with each other;

FIG. 8 is a sectional view illustrating a state after the terminal and the contact pin according to First Embodiment are coupled with each other;

FIG. 9 is a sectional view illustrating a state where a screw according to First Embodiment is screwed;

FIG. 10A is a (first) view illustrating procedures for attaching a power supply cord according to First Embodiment;

FIG. 10B is a (second) view illustrating the procedures for attaching the power supply cord according to First Embodiment;

FIG. 10C is a (third) view illustrating the procedures for attaching the power supply cord according to First Embodiment;

FIG. 11 is an external perspective view of a contact pin according to Second Embodiment;

FIG. 12 is an exploded perspective view of the contact pin according to Second Embodiment;

FIG. 13 is an enlarged view of a protruded portion according to Second Embodiment;

FIG. 14 is a sectional view before a terminal and a contact pin according to Second Embodiment are coupled with each other;

FIG. 15 is a sectional view in the middle of coupling the terminal and the contact pin according to Second Embodiment together;

FIG. 16 is a sectional view after the terminal and the contact pin according to Second Embodiment are coupled with each other;

FIG. 17 is a conceptual diagram of elasticity of the contact pin according to Second Embodiment; and

FIG. 18 is a perspective view illustrating a shape of a contact pin according to Third Embodiment;

### DESCRIPTION OF EMBODIMENTS

In a technique in the related art, for example, when any one of a pin terminal block and a screw terminal block is selected and is attached to a case, corresponding one of pin connection using a pin and screw connection using a screw terminal fitting may be performed. However, it is not possible to perform connection corresponding to both the forms of use.

Hereinafter, embodiments suitable for a technique that is capable of (may be used in common for) performing both of contactor connection and connection with a power supply cord by screwing of a screw are described in detail with reference to the accompanying drawings.

### First Embodiment

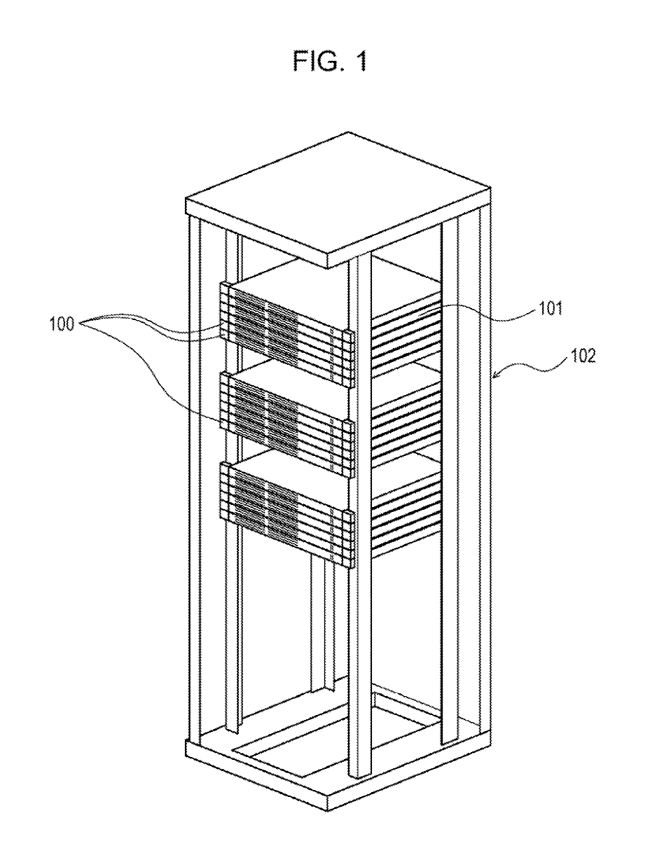

FIG. 1 is a perspective view illustrating an entire configuration of a rack (electronic device system in which a plurality of electronic devices are mounted on a rack), to which electronic devices according to First Embodiment are attached. In FIG. 1, electronic devices 100 of Embodiments according to the disclosure may be, for example, an electronic device provided with a variety of functions to build an optical transmission system. Each electronic device 100 is driven by being separately supplied with power.

The electronic devices 100 are attached on a rack 102 in a state of being mounted on a sub-rack 101. One or a plurality of electronic devices 100 may be mounted on one sub-rack 101. A plurality of sub-racks 101 may be attached to one rack 102.

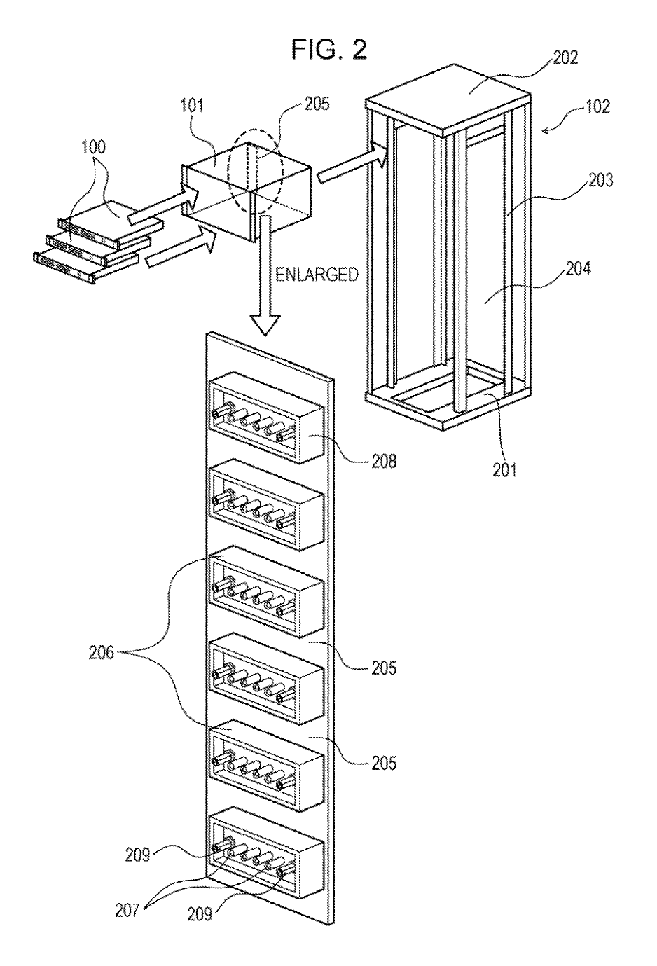

FIG. 2 is an exploded perspective view of the electronic devices, the rack and sub-rack to which the electronic devices are attached, and a power supply bus bar according to First Embodiment. In FIG. 2, in the rack 102, a bottom plate 201 and a top plate 202 are connected to each other by struts 203. A panel 204 that covers each of the back surface, side surface, or front surface of the rack 102 may be provided on the back surface, side surface, or front surface of the rack 102. The panel 204 provided on the back surface or front surface of the rack 102 may be a door which is openable and closable.

The sub-rack 101 is shaped into a box, which is made of plate members configured as a bottom surface, a top surface, both side surfaces, and a back surface and of which one surface on a front surface side is opened. The sub-rack 101 is attached to the rack 102 by being screwed with the struts 203 of the rack 102, between the bottom plate 201 and top plate 202 of the rack 102. The electronic devices 100 may be inserted into or removed from the sub-rack 101 via an opening on the front surface side.

The plate members on walls of the sub-rack 101 are provided with a guide rail (not illustrated) at a position on an inner side of the sub-rack 101. The guide rail is provided with a fixing member including a hook that engages with the electronic device 100. The electronic devices 100 may be fixed to the sub-rack 101 via the guide rail by engaging with the hook in a state of being placed on the guide rail. The guide rail may be slidable in a direction of being pulled out to the front surface side of the sub-rack 101. Accordingly, attaching or detaching the electronic devices 100 to or from the sub-rack 101 may be easily performed.

The sub-rack 101 is provided with a power supply bus bar 205. The power supply bus bar 205 is provided on a plate member on a back surface side of the sub-rack 101. The power supply bus bar 205 is provided with a plurality of power supply connectors 206. The plurality of power supply connectors 206 are provided with a connector case 208 that corresponds to each electronic device 100 and supports, for example, contact pins 207, which are projected contactors for power supply. Each contact pin 207 is connected to a power supply (not illustrated).

In addition, fitting-positioning guide pins 209 are provided in the connector case 208. The plurality of power supply connectors 206 are disposed in a state where the connector cases 208 are arranged in a direction in which the electronic devices 100 are mounted in the sub-rack 101, that is, in an up-and-down direction.

The electronic devices 100 are not limited to devices attached to the rack 102 via the sub-rack 101. The electronic device 100 may be directly attached to the rack 102. In this case, the power supply bus bar 205 is provided in the rack 102.

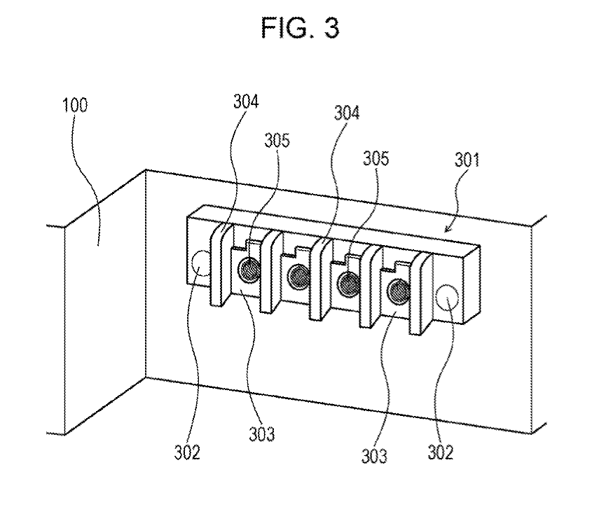

FIG. 3 is an external perspective view of a connector-and-terminal block according to First Embodiment. In FIG. 3, a connector-and-terminal block 301 is provided on a back surface side of the electronic device 100. The connector-and-terminal block 301 is provided with fitting-positioning guide holes 302. The fitting-positioning guide holes 302 have a concaved shape that is concaved from the back surface side to a front surface side of the electronic device 100. The fitting-positioning guide holes 302 position the electronic device 100 with respect to the sub-rack 101 by the fitting-positioning guide pins 209 provided in the power supply bus bar 205 being fitted thereto.

A plurality of (two, in this embodiment) fitting-positioning guide holes 302 are provided. Accordingly, the position of the electronic device 100 with respect to the sub-rack 101 may be determined by two or more points in a plane orthogonal to a direction in which the fitting-positioning guide pins 209 are fitted to the fitting-positioning guide holes 302. Accordingly, the accuracy of the position of the electronic device 100 with respect to the sub-rack 101 may be ensured and the connector-and-terminal block 301 of the electronic device 100 and the power supply bus bar 205 may be easily connected to each other.

The connector-and-terminal block 301 is provided with a plurality of terminals (contact blocks) 303. The plurality of terminals 303 are disposed so as to be arranged in a straight line, and the respective terminals 303 are partitioned by ribs 304. An insulating material is used for the ribs 304, and the ribs 304 reduce a short circuit between the terminals 303.

The plurality of terminals 303 are disposed between the two fitting-positioning guide holes 302 so as to be arranged in a straight line that joins the two fitting-positioning guide holes 302.

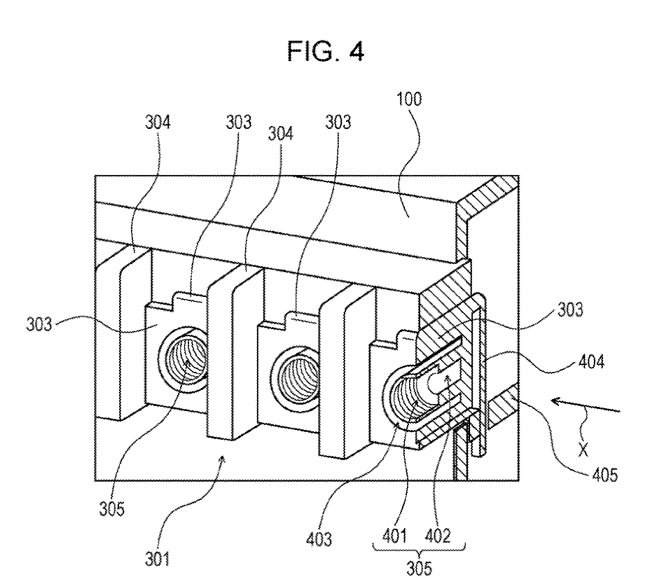

FIG. 4 is a partially sectional view of the connector-and-terminal block according to First Embodiment. In FIG. 4, the terminal 303 has the hole portions 305 into which the contact pins 207 are inserted. The hole portions 305 have a concaved shape that is concaved from the back surface side to the front surface side of the electronic device 100. The terminal 303 is electrically connected to the contact pins 207 by the contact pins 207 being inserted into the hole portions 305 and is supplied with power to the electronic device 100 via the contact pins 207.

In addition, FIG. 4 illustrates a state where the connector-and-terminal block 301 is cut along a plane that is in parallel with a direction of the depths of the hole portions 305 and that is orthogonal to a direction in which the terminals 303 are disposed. In FIG. 4, the hole portions 305 are each provided with a first connection portion 401 and a second connection portion 402.

The first connection portion 401 is provided closer to the back surface side of the electronic device 100 than the second connection portion 402, that is, on an insertion port side of the contact pin 207. The inner diameter of the first connection portion 401 is larger than the inner diameter of the second connection portion 402. In addition, the inner diameter of the first connection portion 401 is larger than the diameter of the contact pin 207. A female screw groove is formed in the inner circumferential surface of the first connection portion 401.

The second connection portion 402 is provided closer to the inside in the hole portion 305 than the first connection portion 401. That is, the second connection portion 402 is provided closer to the front surface side than the first connection portion 401, that is, is provided inside of the first connection portion 401 when seen from the insertion port. The inner diameter of the second connection portion 402 is approximately the same as the diameter of the contact pin 207, and is smaller than the inner diameter of the first connection portion 401.

In addition, it is preferable that the inner circumferential surface of the second connection portion 402 be smoother than the inner circumferential surface of the first connection portion (for example, the female screw groove that is formed in the inner circumferential surface of the first connection portion 401 is not formed in the second connection portion 402). The contact pin 207 inserted in the hole portion 305 is fitted to the second connection portion 402.

In a state where the contact pin 207 is fitted to the second connection portion 402, the inner circumferential surface of the second connection portion 402 and the contact pin 207 are in contact with each other. It is desirable that the first connection portion 401 be continuous with the second connection portion 402. However, the first connection portion 401 and the second connection portion 402 may not necessarily be continuous with each other.

A contactor guard clearance portion 403 is provided in the vicinity of the hole portion 305. The contactor guard clearance portion 403 is realized as an annular groove provided in the outer circumference of the hole portion 305. The contactor guard clearance portion 403 is concaved from a contact surface at the same depth as the depth of the hole portion 305. Due to the contactor guard clearance portion 403, the hole portion 305 (the first connection portion 401 and the second connection portion 402) is formed on an inner circumferential side of a cylindrical portion.

The terminal 303 is connected to a circuit (not illustrated) of the electronic device 100. Accordingly, power supplied from the contact pin 207 via the terminal 303 may be supplied to the circuit of the electronic device 100. In this embodiment, a conductive material including a metal material is used for the terminal 303 and the terminal 303 is integrally provided with the hole portion 305 and the contactor guard clearance portion 403. Accordingly, the terminal 303 and the circuit of the electronic device 100 may be electrically connected to each other by connecting a substrate connection lead 404, which is a part of the terminal 303, to the circuit of the electronic device 100.

A portion in the vicinity of the contactor guard clearance portion 403, which is a surface on the back surface side of each terminal 303, abuts against the bottom surface of the connector case 208 of the power supply connector 206 when the connector-and-terminal block 301 and the power supply connector 206 are coupled with each other. Accordingly, since positioning of the electronic device 100 with respect to the sub-rack 101 in a direction where the contact pins 207 are inserted and removed into and from the terminals 303 may be performed, the accuracy of the position of the electronic device 100 with respect to the sub-rack 101 may be ensured.

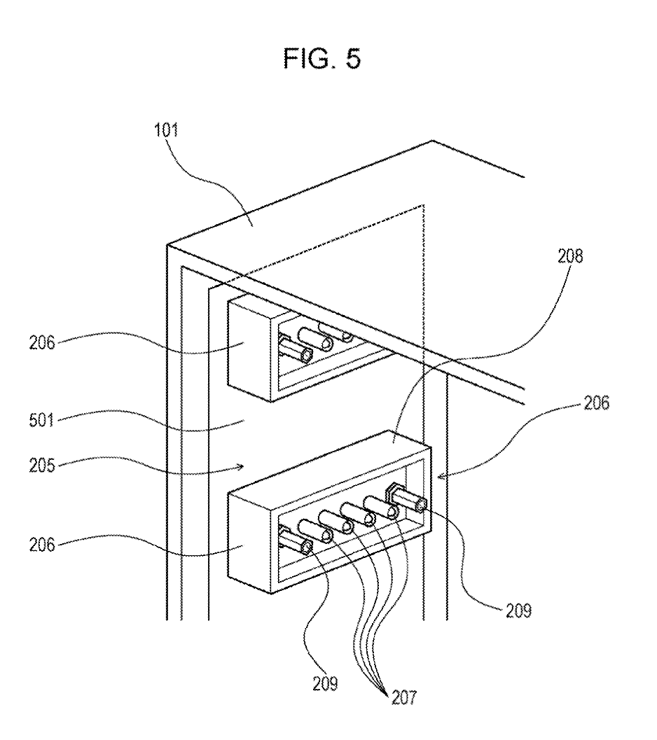

FIG. 5 is an external perspective view of the power supply connectors according to First Embodiment. In FIG. 5, the power supply bus bar 205 is provided with the plurality of power supply connectors 206 disposed on a panel 501. Each of the plurality of power supply connectors 206 is provided with a plurality of contact pins 207 and a pair of fitting-positioning guide pins 209. The plurality of contact pins 207 are disposed in a straight line and adjacent contact pins 207 are provided at the same intervals as the intervals between the hole portions 305 in the connector-and-terminal block 301.

The pair of fitting-positioning guide pins 209 is provided in a straight line where the plurality of contact pins 207 are arrayed such that the plurality of contact pins 207 are interposed therebetween. The pair of fitting-positioning guide pins 209 is provided at the same interval as that of the interval between the fitting-positioning guide holes 302 so as to correspond to the fitting-positioning guide holes 302 in the connector-and-terminal block 301.

The connector case 208 of the power supply connector 206 protrudes in a rectangular shape from the power supply bus bar 205. The connector case 208 is fitted to the connector-and-terminal block 301 so as to cover the outer circumferential surface of the connector-and-terminal block 301 and the ribs 304 from the back surface side of the electronic device 100. The position of the connector case 208, which is in a state of being fitted to the connector-and-terminal block 301 is fixed by the outer circumferential surface of the connector-and-terminal block 301 and the ribs 304. Consequently, the power supply connector 206 and the connector-and-terminal block 301 may be stably coupled with each other.

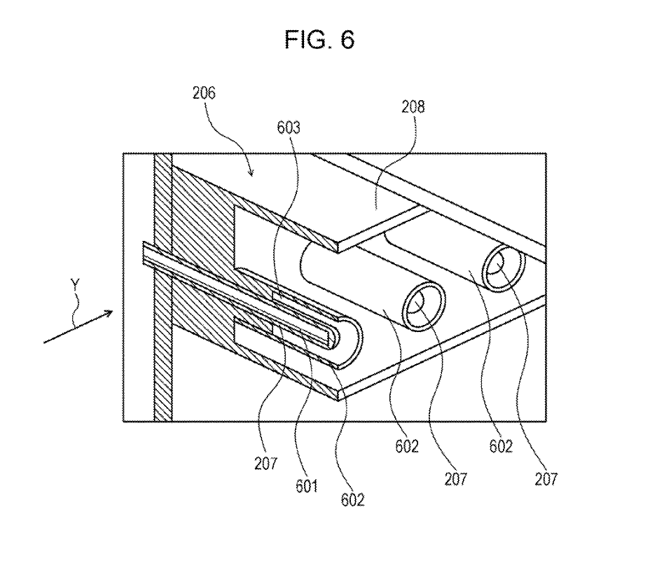

FIG. 6 is a partially sectional view of the power supply connector according to First Embodiment. FIG. 6 illustrates a state where the power supply bus bar 205 and one contact pin 207 in the power supply connector 206 are cut along a plane which passes through the central axis of the contact pin 207 and is orthogonal to a direction in which the contact pins 207 are disposed.

In FIG. 6, one end of the contact pin 207 in the power supply connector 206 protrudes to the front surface side of the sub-rack 101, and the other end thereof penetrates the panel 204 of the power supply bus bar 205 and is connected to the power supply (not illustrated). The contact pin 207 has slits 601 and has structure of a banana jack (banana plug). The contact pin 207 having the structure of the banana jack has springiness.

Contactor guards 602, which are covering members for covering contact pins, are provided on outer circumferential sides of the contact pins 207 so as to cover the contact pins 207. The contactor guards 602 have a cylindrical shape and are provided such that the central axes of the cylinders coincide with the central axes of the contact pins 207. An annular groove 603 is formed between the outer circumferential surface of the contact pin 207 and the inner circumferential surface of the contactor guard 602.

The thickness of the contactor guard 602 is the same as the width of the annular groove 603 that forms the contactor guard clearance portion 403 or is smaller than the width. Accordingly, the contactor guards 602 and the contactor guard clearance portions 403 do not obstruct connection between the terminals 303 and the contacts pins 207. By the contactor guards 602 being provided, it is possible to avoid the contact pins 207 that are provided so as to protrude from the power supply bus bar 205 being damaged or short-circuited as a result of coming into contact with surrounding members. In addition, since the contact pins 207 have structure in which the contact pins 207 are not exposed, the occurrence of an electric shock caused by accidently touching the contact pins 207 may be effectively reduced.

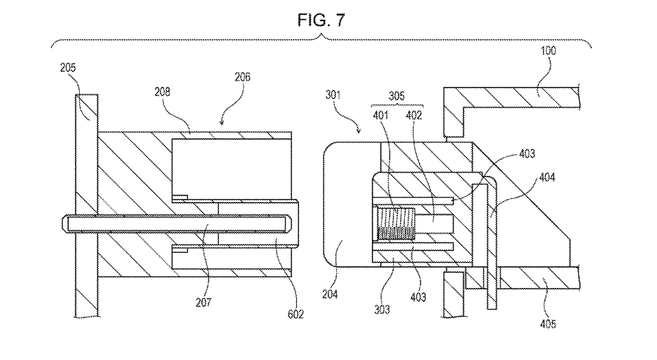

FIG. 7 is a sectional view illustrating a state before the terminal and the contact pin according to First Embodiment are coupled with each other. FIG. 7 illustrates a state before the terminal 303 seen from an arrow X direction in FIG. 4 and the contact pin 207 seen from an arrow Y direction in FIG. 6 are coupled with each other. In FIG. 7, when coupling the terminal 303 and the contact pin 207 together, the terminal 303 in the connector-and-terminal block 301 and the contact pin 207 in the power supply connector 206 are set to face each other. Since the guide rail is provided in the sub-rack 101, the terminals 303 and the contact pins 207 may be easily and reliably set to face each other by placing the electronic device 100 on the guide rail.

The electronic device 100 is inserted into the sub-rack 101 by inserting the fitting-positioning guide pins 209 into the fitting-positioning guide holes 302 while the terminals 303 and the contact pins 207 face each other, when coupling the terminals 303 and the contact pins 207 together. Accordingly, the connector-and-terminal block 301 is fitted to the connector case 208 such that the outer circumferential surface of the connector-and-terminal block 301 and the ribs 304 are covered with the connector case 208 from the back surface side of the electronic device 100.

In addition, by the connector-and-terminal block 301 being fitted to the connector case 208, the contact pin 207 is inserted into the hole portion 305 and a tip of the contact pin 207 passes through the first connection portion 401 and reaches the second connection portion 402, and by the contact pin 207 being further inserted to the inside, the terminal 303 and the contact pin 207 are coupled with each other. Furthermore, the contactor guard 602 is fitted to the contactor guard clearance portion 403 by the connector-and-terminal block 301 being fitted to the connector case 208.

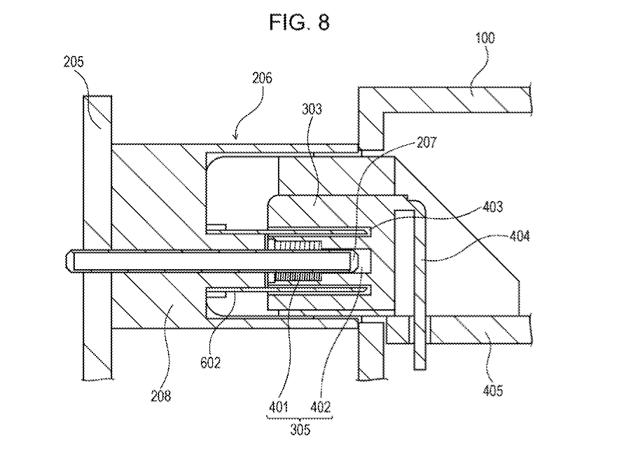

FIG. 8 is a sectional view illustrating a state after the terminal and the contact pin according to First Embodiment are coupled with each other. FIG. 8 illustrates a state where the terminal 303 seen in the arrow X direction in FIG. 4 and the contact pin 207 seen in the arrow Y direction in FIG. 6 are coupled with each other. In FIG. 8, the terminal 303 and the contact pin 207 are coupled with each other by the contact pin 207 being inserted into the hole portion 305 of the terminal 303.

Since the inner diameter of the second connection portion 402 in the terminal 303 is the same as the diameter of the contact pin 207, the contact pin 207 is electrically connected to the terminal 303 by being inserted into the hole portion 305. However, since the inner diameter of the first connection portion 401 is larger than the diameter of the contact pin 207, the contact pin 207 does not come into contact with the first connection portion 401. As in the above description, simply by inserting the electronic device 100 into the sub-rack 101 along the guide rail, connection for receiving power from the sub-rack 101 is completed.

As a form of use of the electronic device 100, a form of use in which the electronic device 100 is used without using the sub-rack 101 may be assumed in addition to a form of use in which the electronic device 100 is mounted on the sub-rack 101 as described above. Specifically, for example, a form of use in which the electronic device 100 is set up and is used on a desk and a form of use in which power is directly supplied to the electronic device 100 from a power supply device already included may be assumed. In addition, a form of use in which power is directly supplied to the electronic device 100 without using the sub-rack 101 may be assumed in order to use a space in the rack 102 with high efficiency.

In the related art, in order to realize such a form of use, a dedicated attachment for power supply is attached to the electronic device 100 and power is supplied to the electronic device 100 via the dedicated attachment. The dedicated attachment is provided with a dedicated terminal block to which a power supply cord connected to a power supply and having a tip provided with a crimp terminal is connected by screwing, a connector to connect the dedicated attachment and the electronic device 100 together, and a printed circuit board, on which a circuit used for controlling supply of power via the dedicated attachment is mounted (both of the dedicated attachment and the printed circuit board are not illustrated).

However, it is desirable that such a dedicated attachment be attached to each electronic device 100, and thus the burden of work is great at the time of setting up in a case where a great number of the electronic devices 100 are introduced. In addition, in a case where a lack of preparation of the dedicated attachment or a loss of the dedicated attachment occurs at the time of setting up the electronic device 100, work of building a system of the electronic device 100 stops in the field and the impact of the stop is extensive.

On the contrary, since the terminal 303 of the electronic device 100 has the hole portion 305 provided with the first connection portion 401 and the second connection portion 402, a power supply cord provided with the crimp terminal may be directly connected to the electronic device 100 by a screw, instead of the contact pin 207, being screwed with the hole portion 305 without the dedicated attachment being attached.

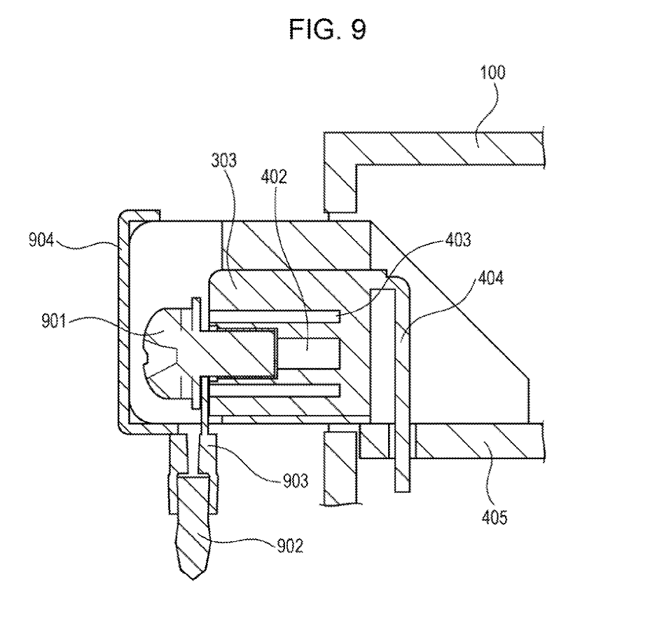

FIG. 9 is a sectional view illustrating a state where the screw according to First Embodiment is screwed. FIG. 9 illustrates a section obtained by cutting the electronic device 100 which is in a state where the screw is screwed with the terminal 303, at the same position as in FIG. 4. In FIG. 9, instead of the contact pin 207 being inserted and fitted to the second connection portion 402, a screw 901 is screwed with the female screw groove provided in the inner circumferential surface of the first connection portion 401 of the hole portion 305. A screw having the same pitch as the pitch of the female screw groove is used as the screw 901.

The screw 901 is screwed with the female screw groove in a state where a crimp terminal 903 attached to a tip of the power supply cord 902 is put in between the screw 901 and the terminal 303. The crimp terminal 903 may be a circular R-terminal 303 (ring terminal) or may be a Y-terminal 303 of which a tip is opened. Accordingly, the terminal 303 and the power supply cord 902 may be electrically connected to each other via the crimp terminal 903.

In a form of use in which the terminal 303 and the power supply cord 902 are electrically connected to each other via the crimp terminal 903, a terminal protecting cover 904 is attached to the connector-and-terminal block 301. It is preferable that the terminal protecting cover 904 have a shape which covers the entire terminals 303 with a single piece of attaching work. The terminal protecting cover 904 may be formed, for example, in a shape that allows the terminal protecting cover 904 to engage with the ribs 304.

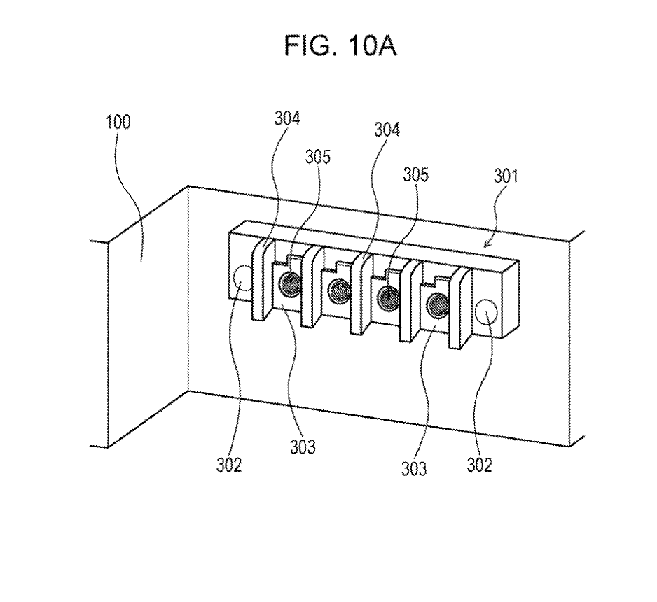

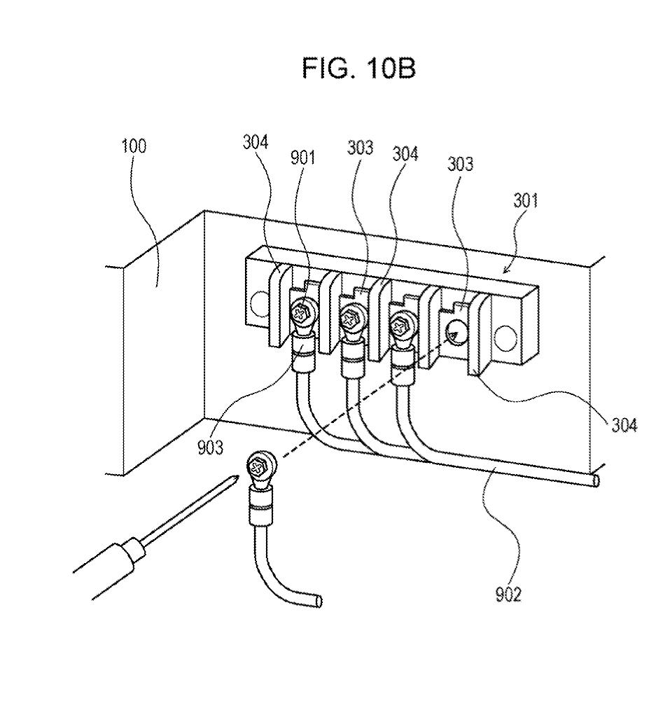

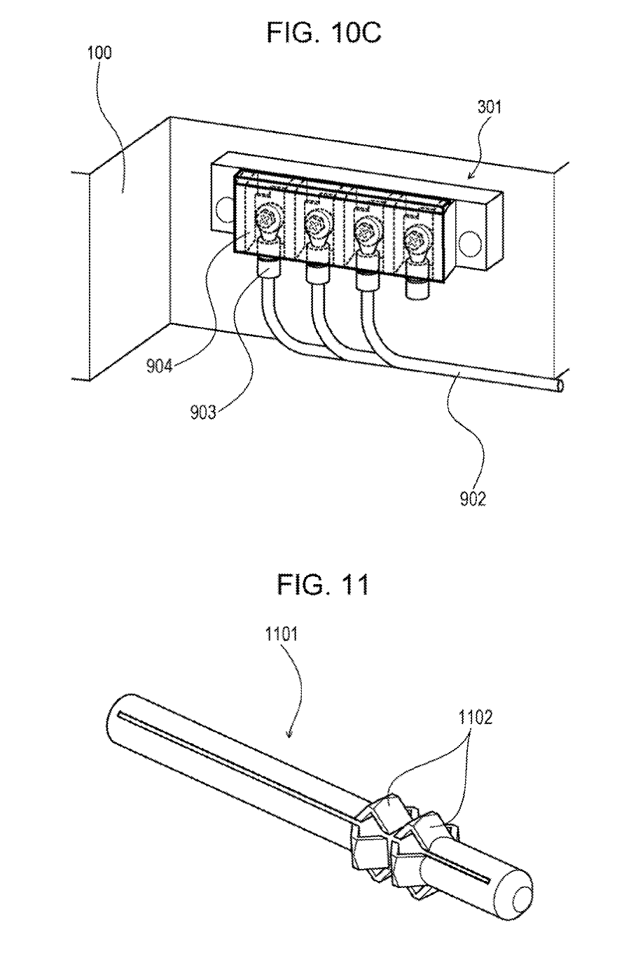

FIG. 10A to FIG. 10C are views illustrating procedures for attaching the power supply cords according to First Embodiment. When attaching the power supply cords 902 to the connector-and-terminal block 301, first, as illustrated in FIG. 10B, the screws 901 inserted in the ring terminals of the crimp terminals 903 are screwed with the connector-and-terminal block 301 illustrated in FIG. 10A, which is in a state of not being coupled with the power supply connector 206.

FIG. 10B illustrates a state where three out of the four screws 901 are already screwed and the last fourth screw 901 is about to be screwed. Although the power supply cord 902 that is connected to the fourth screw which is about to be screwed is illustrated separately from the power supply cords 902 connected to other screws in FIG. 10B for convenience of description, all of the power supply cords 902 are connected in reality (refer to FIG. 10C).

The screws 901 may be screwed using a driver in general. The driver may be appropriately chosen according to the shape of grooves or holes (a cross hold, a slot, or a hexagon hole) formed in the heads of the screws 901. In this manner, all of the terminals 303 and the power supply cords 902 may be connected to each other via the crimp terminals 903.

Next, as illustrated in FIG. 10C, the terminal protecting cover 904 is attached to the connector-and-terminal block 301. It is preferable that the terminal protecting cover 904 have a shape which covers the entire terminals 303 with a single piece of attaching work. Specifically, for example, the terminal protecting cover 904 may be a plate-shaped member held between the ribs 304 on the both ends of the plurality of disposed terminals 303, or may be a member having a shape provided with a plate-shaped member covering all of the ribs 304 and a claw that engages the plate-shaped member with the connector-and-terminal block 301 (for example, the ribs 304).

In addition, the terminal protecting cover 904 may be transparent or may be colored. If the terminal protecting cover 904 is transparent, a connection state of the screws 901 (state as to screwing is loose or not) may be seen without taking off the terminal protecting cover 904. In addition, there may be a color (for example, yellow) to warn that a current is flowing.

As described hereinbefore, in the electronic device 100, the terminals 303 that receive power have the hole portions 305 which are provided with the first connection portions 401 and the second connection portions 402. The first connection portions 401 are provided on the insertion port side of the projected contact pins 207 for power supply, and female screw grooves are formed in the inner circumferential surfaces thereof. The second connection portions 402 continuous with the first connection portions 401 are provided inside the first connection portions 401 when seen from the insertion ports, and the contact pins 207 are fitted to the inner circumferential surfaces.

Accordingly, the inner circumferential surfaces of the second connection portions 402 of the electronic device 100 and the contact pins 207 may come into contact with each other over a wide area and power may be more reliably supplied to the electronic device 100 when mounting on the rack 102 (specifically, the sub-rack 101).

In addition, since the electronic device 100 is easily attached to and detached from the sub-rack 101, both types of connection may be performed without changing the specification of the electronic device 100, and modes of connection with power supply cords may be easily switched according to a form of use. That is, both types of connection may be performed by easily switching between contact pin connection and connection with power supply cords by screwing of the screws 901. In addition, accordingly, the electronic device 100 may be used in an environment desired by a user and the versatility of the electronic device 100 may be improved.

In addition, the contact pins 207 coupled with the terminals 303 of the electronic device 100 are provided so as to oppose the electronic device 100 on the rack 102, and the contact pins 207 are inserted into the hole portions 305 of the terminals 303 by the electronic device 100 being placed at a predetermined position on the rack 102.

Accordingly, the terminals 303 and the contact pins 207 may be reliably coupled with each other only with work of placing the electronic device 100 at the predetermined position on the rack 102. Accordingly, modes of connection with power supply cords may be easily switched, according to a form of use, without performing complicated work such as checking by visual inspection of a positional relationship between the terminals 303, which is provided on the back surface of the electronic device 100, and the contact pins 207. Therefore, connection may be made through a plurality of modes of connection.

In addition, in the terminals 303 of the electronic device 100, the power supply cords 902, instead of the contact pins 207, may be directly connected to the first connection portions 401 by screwing of the screws 901 and the female screw grooves, which are for connecting power supply cords. Accordingly, the power supply cords 902 may be directly connected with work of simply screwing the screws 901 into the first connection portions 401. As in the above description, the electronic device 100 may easily switch forms of supply of power even in a specification in which power is not supplied from the contact pins 207. Therefore, a plurality of forms of supply of power may be used.

### Second Embodiment

Next, Second Embodiment is described. In Second Embodiment, the same portions as in the aforementioned First Embodiment are indicated by the same reference signs and description thereof are omitted.

FIG. 11 is an external perspective view of a contact pin according to Second Embodiment. In FIG. 11, a contact pin 1101 of Second Embodiment has protruded portions 1102 that protrude in a direction (radial direction of the contact pin 1101) orthogonal to the longitudinal direction, at predetermined positions in a longitudinal direction of the contact pin 1101 (central axis direction of the contact pin 1101). In total, eight protruded portions 1102 are provided, four on a concentric circle of which the center is the central axis of the contact pin 1101 at two positions in the central axis direction.

The number of protruded portions 1102 is not limited to four on the concentric circle, and may be more than or smaller than four. Although it is preferable that the protruded portions 1102 be provided at equal intervals on the concentric circle of which the center is the central axis of the contact pin 1101, the disposition is not limited thereto. In addition, the number of positions of protruded portions 1102 is not limited to two in the central axis direction, and the number may be one or more than two. In addition, the number may be one. It is preferable that a plurality of protruded portions 1102 be provided in the central axis direction.

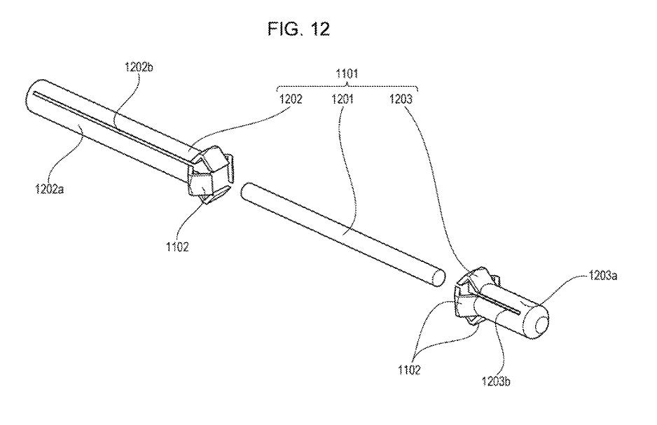

FIG. 12 is an exploded perspective view of the contact pin of Second Embodiment. In FIG. 12, the contact pin 1101 has a connecting core 1201, which is a rod-shaped core portion, a pin rear end portion 1202, and a pin front end portion 1203. The connecting core 1201 is formed in a cylindrical shape. The inner circumferential sides of the pin rear end portion 1202 and the pin front end portion 1203 are cavities and cover the connecting core 1201 from both ends of the connecting core 1201.

The pin rear end portion 1202 and the pin front end portion 1203 are provided with axial portions 1202a and 1203a, which cover the external surface of the connecting core 1201, and the protruded portions 1102, respectively. Adjacent protruded portions 1102 in the pin rear end portion 1202 and the pin front end portion 1203 are independent of each other. The protruded portions 1102 are formed by folding the tip of the axial portion 1203a which functions as a flat spring member. In addition, the axial portions 1202a and 1203a are divided by slits 1202b and 1203b provided at positions corresponding to positions of boundaries between the protruded portions 1102, and each of the slits 1202b and 1203b is continuous with the corresponding protruded portion 1102.

The pin rear end portion 1202 and the connecting core 1201 are fixed to each other by pressing the connecting core 1201 in the axial portion 1202a of the pin rear end portion 1202. Similarly, the pin front end portion 1203 and the connecting core 1201 are fixed to each other by pressing the connecting core 1201 in the axial portion 1203a of the pin front end portion 1203. A conductive material is used for the connecting core 1201, the pin rear end portion 1202, and the pin front end portion 1203, and consequently, the pin rear end portion 1202 and the pin front end portion 1203 are electrically connected to each other by the connecting core 1201.

The pin rear end portion 1202, the pin front end portion 1203, and the connecting core 1201 are not limited to being fixed by pressing in. The pin rear end portion 1202, the pin front end portion 1203, and the connecting core 1201 may be fixed by carrying out solder welding on end portions of the connecting core 1201, or for example, by an adhesive in which a conductive material is used. Even in a case where either method is used, the contact pin 1101 and the terminal 303 may be electrically connected to each other in a state where the fixing of the pin rear end portion 1202 and the connecting core 1201 and the fixing of the pin front end portion 1203 and the connecting core 1201 are completed.

Each of the ridgelines of the protruded portions 1102 provided in the pin rear end portion 1202 and each of the ridgelines of the protruded portions 1102 provided in the pin front end portion 1203 are formed in an R-shape having the same curvature as that of the inner circumferential surfaces of the first connection portions 401. The inner circumferential surfaces of the axial portions 1202a and 1203a are formed in a shape that curves at a curvature corresponding to the curvature of the external surface of the connecting core 1201. The outer circumferential surface of the axial portion 1203a of the pin front end portion 1203 is formed in an R-shape having the same curvature as those of the inner circumferential surfaces of the second connection portions 402.

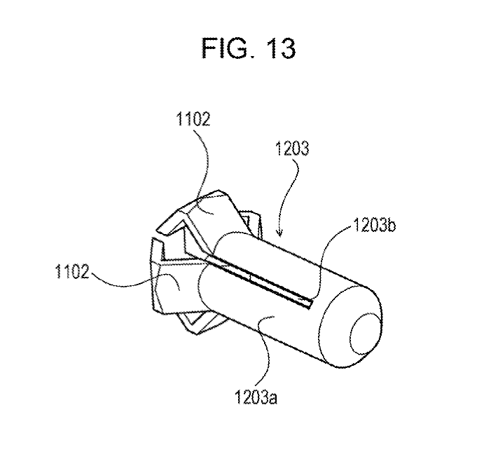

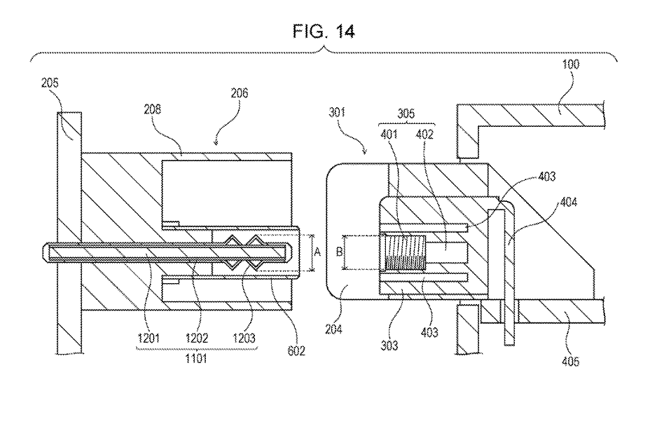

FIG. 13 is an enlarged view of the protruded portions according to Second Embodiment. In FIG. 13, the protruded portions 1102 of the pin front end portion 1203 are formed by bending a part of the pin front end portion 1203 into an angled shape. The protruded portions 1102 have springiness (elasticity) due to the angles shape. In addition, the protruded portions 1102 have springiness due to the axial portion 1203a since the axial portion 1203a continuous with the protruded portions 1102 is divided by the slits 1203b corresponding to each protruded portion 1102. However, the slits 1203b may not be provided if the springiness of the protruded portions 1102 may be ensured.

Although not illustrated, the protruded portions 1102 of the pin rear end portion 1202 also have the same configuration as those of the protruded portions 1102 of the pin front end portion 1203 illustrated in FIG. 13.

FIG. 14 is a sectional view before the terminal and the contact pin according to Second Embodiment are coupled with each other. FIG. 14 illustrates a section obtained by cutting the contact pin 1101 and the terminal 303 of Second Embodiment at the same position as in FIG. 7. In FIG. 14, the protruded portions 1102 are formed such that the outer diameter of contact pin 1101 (dimension indicated by a reference sign A in FIG. 14), which is determined by the ridgelines of the protrusions, is larger than the inner diameter of the first connection portion 401 (dimension indicated by a reference sign B in FIG. 14).

The electronic device 100 is inserted into the sub-rack 101 by inserting the fitting-positioning guide pins 209 into the fitting-positioning guide holes 302 with a state where the terminal 303 and the contact pin 1101 face each other when coupling the terminal 303 and the contact pin 1101 together. Accordingly, the contact pin 1101 is inserted into the hole portion 305 of the terminal 303.

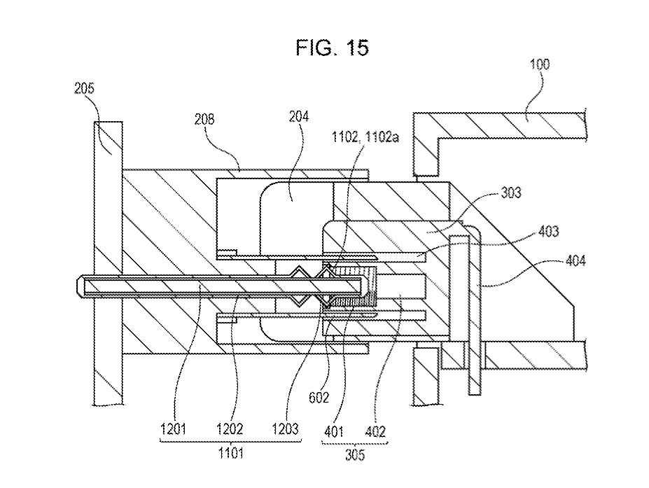

FIG. 15 is a sectional view in the middle of coupling the terminal and the contact pin according to Second Embodiment together. FIG. 15 illustrates a state where the electronic device 100 is further inserted into the sub-rack 101 compared to the state illustrated in FIG. 14. In FIG. 15, in the contact pin 1101 inserted in the hole portion 305, first, the protruded portions 1102 provided in the pin front end portion 1203 (hereinafter, referred to as “first protruded portions 1102a”) abut against the inner circumferential surface of the first connection portion 401.

Since the first protruded portions 1102a are independent of each other, the axial portion 1203a is divided by the slits 1203b corresponding to each of the first protruded portions 1102a, and the first protruded portions 1102a are formed by folding the tip of the axial portion 1203a, the axial portion 1203a that is continuous with the first protruded portions 1102a which abut against the inner circumferential surface of the first connection portion 401 functions as the flat spring member. Thus, the axial portion 1203a warps in a direction where the first protruded portions 1102a are pressed to the connecting core 1201 due to the springiness of the axial portion 1203a with an end portion of the connecting core 1201 on a pin front end portion 1203 side as a fulcrum. Accordingly, the protruded portions 1102, in which elastic members of which heights in a direction orthogonal to the longitudinal direction change are used, may be realized.

When the electronic device 100 is further inserted into the sub-rack 101 with a state where the first protruded portions 1102a abut against the inner circumferential surface of the first connection portion 401, the first protruded portions 1102a pass through the first connection portion 401 with a state where the axial portion 1203a is warped. At this time, the first protruded portions 1102a abut against the inner circumferential surface of the first connection portion 401 at a fixed pressure due to the springiness of the axial portion. In addition, when the electronic device 100 is further inserted into the sub-rack 101 with a state where the first protruded portions 1102a abut against the inner circumferential surface of the first connection portion 401, the protruded portions 1102 (hereinafter, referred to as “second protruded portions 1102b”) provided in the pin rear end portion 1202 abuts against the inner circumferential surface of the first connection portion 401.

Since the respective second protruded portions 1102b are independent of each other and the axial portion 1202a is divided by the slits corresponding to each of the second protruded portions 1102b, the axial portion 1202a warps in a direction where the second protruded portions 1102b are pressed to the connecting core 1201 due to the springiness of the axial portion 1202a with an end portion of the connecting core 1201 on a pin rear end portion 1202 side as a fulcrum. The second protruded portions 1102b pass through the second connection portion 402 with a state where the axial portion 1202a is warped. At this time, the second protruded portions 1102b abut against the inner circumferential surface of the first connection portion 401 at a fixed pressure due to the springiness of the axial portion 1202a.

A force to cause the axial portions 1202a and 1203a to return to original shapes thereof is applied to the first protruded portions 1102a and the second protruded portions 1102b that pass through the first connection portion 401 due to the springiness of the axial portions. Accordingly, every time each of the first protruded portions 1102a and the second protruded portions 1102b pass through an unevenness formed by the female screw groove, those skilled in the art who insert the electronic device 100 into a sub-rack have a clicking feeling.

A clicking feeling occurs due to the axial portions 1202a and 1203a in warped states repeating a series of changes of returning to original shapes thereof due to springiness when the first protruded portions 1102a and the second protruded portions 1102b change from a state of abutting against the crest of the female screw groove to a state of abutting against the root of the female screw groove. With continuous insertion of the contact pin 1101 into the terminal 303, a clicking feeling, which is a sound “clack, clack, . . . ”, may be continuously heard according to an extent of insertion of the contact pin 1101 into the terminal 303.

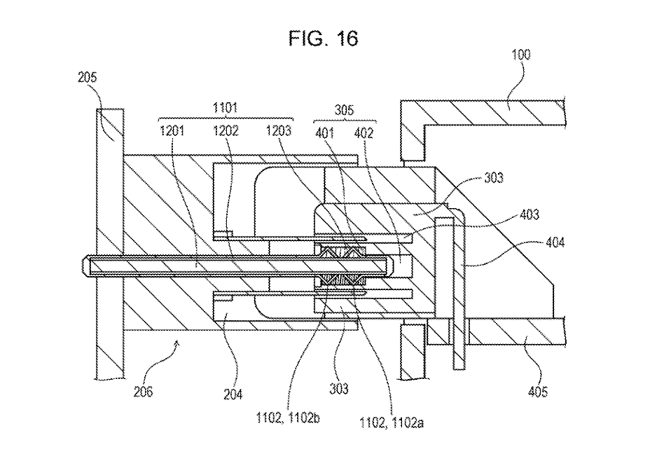

FIG. 16 is a sectional view after the terminal and the contact pin according to Second Embodiment are coupled with each other. FIG. 16 illustrates a state where the electronic device 100 is further inserted into the sub-rack 101 compared to the state illustrated in FIG. 15. In FIG. 16, when the electronic device 100 is further inserted into the sub-rack 101 with a state where the second protruded portions 1102b abut against the inner circumferential surface of the first connection portion 401, the bottom surface of the connector case 208 abuts against the end surface of the terminal 303 on the back surface side and fitting (coupling) of the terminal 303 and the contact pin is completed.

As described above, the pin rear end portion 1202 and the connecting core 1201, and the pin front end portion 1203 and the connecting core 1201 are fixed to each other by carrying out pressing-in or solder welding. Accordingly, in a state where the fitting is completed, electrical connection between the power supply connector 206 and the connector-and-terminal block 301 is ensured.

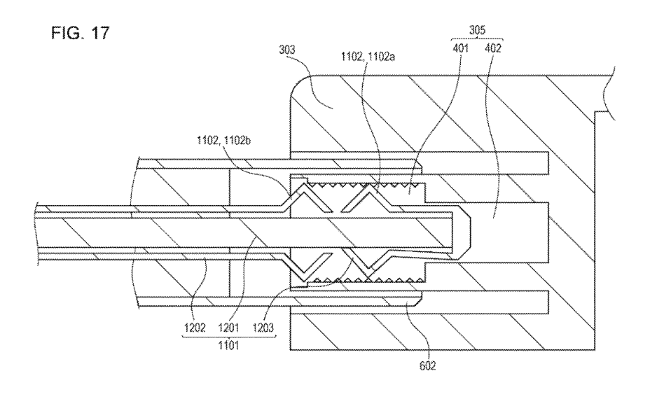

FIG. 17 is a conceptual diagram of the elasticity of the contact pin according to Second Embodiment. FIG. 17 illustrates a state where one of the first protruded portions 1102a abuts against the crest of the female screw groove and is elastically deformed. In FIG. 17, when the first protruded portion 1102a abuts against the crest of the female screw groove, the axial portion continuous with the first protruded portion 1102a warps in a direction of pressing the first protruded portion 1102a to the connecting core 1201 with the end portion of the connecting core 1201 on the pin front end portion 1203 side as a fulcrum. Since the first protruded portions 1102a are independent of each other and the axial portion is divided by the slits corresponding to each of the first protruded portions 1102a, the axial portion warps by the axial portion corresponding to the first protruded portion 1102a abutting against the crest of the female screw groove.

In addition, since the contact pin 1101 has the protruded portions 1102 that protrude in the direction orthogonal to the longitudinal direction at predetermined positions in the longitudinal direction, the contact pin 1101 may reliably come into contact with the inner circumferential surface of the first connection portion 401. Accordingly, only with work of placing the electronic device 100 at a predetermined position on the rack 102, more specifically, for example, inserting the electronic device 100 in a horizontal direction into a predetermined position on the sub-rack 101, the terminals 303 and the contact pins 1101 may be reliably coupled with each other.

In addition, by the elastic members, of which at least the heights in the direction orthogonal to the longitudinal direction change, being used for the protruded portions 1102, those skilled in the art who insert the electronic device 100 into the sub-rack may have a clicking feeling, which is a clacking sound. Accordingly, those skilled in the art may recognize that the terminal 303 and the contact pin 1101 are coupled with each other normally by the senses even if a portion that the terminal 303 and the contact pin 1101 are coupled with each other is not checked by visual inspection. Accordingly, the efficiency of work of coupling the terminal 303 and the contact pin 1101 together may be improved.

In addition, those skilled in the art have a clicking feeling, which is a clacking sound, in a case where the terminal 303 and the contact pin 1101 are coupled with each other normally. Accordingly, based on the number of times a clicking feeling is experienced, those skilled in the art may immediately determine the occurrence of attachment failure and component failure in a case where the number of times is small or in a case where a clicking feeling is not experienced.

Specifically, for example, in a case where the number of times of a clicking feeling is experienced is small, it is determined that attachment is not sufficiently performed and it may be determined that further inserting the electronic device 100 into the sub-rack 101 is desirable. In addition, for example, in a case where a clicking feeling is not experienced, or in a case where a clicking feeling is not experienced even if the electronic device 100 is further inserted, it is determined that an attachment position is shifted or failure in component has occurred and determination to perform the work again may be made quickly. As in the above description, attaching work may be more reliably performed.

In addition, since the elastic members in the contact pin 1101 are flat spring members, the terminal 303 and the contact pin 1101 may be coupled with each other in a state where the contact pin 1101 is caused to reliably come into contact with the terminal 303, using the springiness of the flat spring members. Accordingly, a state where electrical connection between the terminal 303 and the contact pin 1101 may be ensured with a simple configuration.

In addition, since the first protruded portions 1102a and the second protruded portions 1102b are formed by folding the flat spring members, a desirable elastic force may be ensured while restricting an increase in the number of components and a state where electrical connection between the terminal 303 and the contact pin 1101 may be ensured with a simple configuration.

In addition, since the first protruded portions 1102a and the second protruded portions 1102b of the contact pin 1101 have a shape that covers at least a tip portion of a rod-shaped core portion, it may be ensured that the contact pin 1101 is electrically conductive also in a case where the contact pin 1101 is formed of a plurality of members. Accordingly, the contact pin 1101 with high reliability in terms of ensuring electrical connection with the terminal 303 may be easily manufactured compared to a case where the contact pin 1101 provided with the protruded portions 1102 is formed of a single member.

### Third Embodiment

Next, Third Embodiment is described. In Third Embodiment, the same portions as in the aforementioned Embodiments 1 and 2 are indicated by the same reference signs and description thereof are omitted.

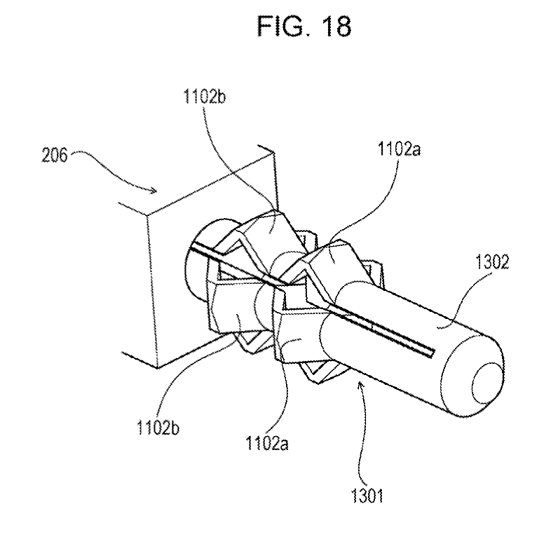

FIG. 18 is a perspective view illustrating a shape of a contact pin according to Third Embodiment. In FIG. 18, a contact pin 1301 according to Third Embodiment is formed by covering the connecting core 1201 with a pin-shaped portion 1302, which is formed by integrating the pin front end portion 1203 and the pin rear end portion 1202 in the contact pin 1101 of the aforementioned Second Embodiment, from the front surface side. The pin-shaped portion 1302 is provided with the first protruded portions 1102a and the second protruded portions 1102b.

Specifically, a part of the pin-shaped portion 1302 is formed by being bent into an angled shape, being bent into an inverted-angled shape, and again being bent into an angled shape. The first protruded portions 1102a and the second protruded portions 1102b have springiness (elasticity) due to each angled shape.

As in the above description, work of covering the connecting core 1201 with the pin-shaped portion 1302 ends with one time by adopting the contact pin 1301 provided with the pin-shaped portion 1302, which is obtained by integrating the pin front end portion 1203 and the pin rear end portion 1202 according to Second Embodiment. Accordingly, an increase in the number of manufacturing processes for the contact pin 1301 may be restricted and the productivity of the contact pin 1301, that is, the productivity of the power supply connector 206 may be improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a terminal configured to receive power and be provided on a back surface side of the electronic device, the terminal including a hole portion configured to be concaved from the back surface side to a front surface side of the electronic device and include
a first connection portion configured to be provided on the back surface side of the electronic device and include an inner circumferential surface having a female screw groove shape, and
a second connection portion configured to be provided on an inner side of the first connection portion, and include an inner diameter smaller than an inner diameter of the first connection portion and an inner circumferential surface smoother than the inner circumferential surface of the first connection portion.

2. The electronic device according to claim 1,
wherein the electronic device is mounted on a rack having a plurality of contactors provided to oppose to the electronic device, and
wherein a contractor of the plurality of contactors is inserted into the hole portion of the terminal by placing the electronic device at a predetermined position on the rack so that the power is supplied to the electronic device through the contractor.

3. The electronic device according to claim 2, wherein the contractor is fitted to the terminal in the second connection portion.

4. The electronic device according to claim 1, wherein a screw for connecting a power supply cord is fitted to the terminal by a female screw groove in the first connection portion.

5. The electronic device according to claim 2, wherein the first connection portion has a groove portion having the female screw groove shape, to which a covering member that is formed on an outer circumference of the contactor at a predetermined interval with the outer circumference of the contactor so as to cover the contactor is fitted.

6. A contactor configured to supply power, the contactor comprising:
a connecting core configured to have a rod-shape;
a pin front end portion configured to cover the connecting core from a first end of the connecting core, and include a first protruded portion having a slit, the first protruded portion being provided on a side opposite to the first end; and
a pin rear end portion configured to cover the connecting core from a second end of the connecting core, and include a second protruded portion having a slit, the second protruded portion being provided on a side opposite to the second end,
wherein protruded portions of the first protruded portion and the second protruded portion protrude at predetermined positions in a longitudinal direction of the connecting core in a direction orthogonal to the longitudinal direction.

7. The contactor according to claim 6, wherein the protruded portions are formed by an elastic member and heights of the protruded portions are changeable at least in the direction orthogonal to the longitudinal direction.

8. The contactor according to claim 7, wherein the elastic member is a flat spring member.

9. The contactor according to claim 8, wherein the protruded portion is formed by folding the flat spring member.

10. An electronic device system comprising:
a rack configured to provide a plurality of contactors to supply power; and
a plurality of electronic devices each configured to be mounted on the rack, and include a terminal configured to receive power and be provided on a back surface side of the electronic device, the terminal including
a hole portion into which a contactor of the plurality of contactors is inserted, configured to include
a first connection portion configured to be provided on the back surface side of the electronic device and include an inner circumferential surface having a female screw groove shape, and
a second connection portion configured to be provided on an inner side of the first connection portion, and include an inner diameter smaller than an inner diameter of the first connection portion and an inner circumferential surface to be fitted to the contactor.

11. The electronic device system according to claim 10, wherein the contactor is provided to oppose to the electronic device, and inserted into the hole portion of the terminal by placing the electronic device at a predetermined position on the rack.

12. The electronic device system according to claim 10, wherein the terminal has a groove portion to which a covering member that is provided on an outer circumference of the contactor so as to cover the contactor at a predetermined interval is fitted.
